(19) United States
(12) Patent Application Publication
(10) Pub. No.: US 2007/0252161 A1
(43) Pub. Date: Nov. 1, 2007

(54) LED MOUNTING STRUCTURES

(75) Inventors: Michael A. Meis, Stillwater, MN (US); Ellen O. Aeling, St. Paul, MN (US); John R. David, Stillwater, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/691,025

(22) Filed: Mar. 26, 2007

Related U.S. Application Data
(60) Provisional application No. 60/744,030, filed on Mar. 31, 2006.

(51) Int. Cl. H01L 33/00

(52) U.S. Cl. 257/88; 257/98; 257/99; 257/E23.004

(57) ABSTRACT

An LED assembly may include a substrate, an elongate mounting structure that is formed in or on the substrate, and an LED that is mechanically secured to the elongate mounting structure. A light producing apparatus may include a substrate, an elongate mounting structure that may be formed in or on the substrate, and a plurality of LEDs that may be removably secured to the elongate mounting structure. A light producing array may include a substrate, a first elongate mounting structure that is formed in or on the substrate, and a second elongate mounting structure that is formed in or on the substrate. A first plurality of LEDs may be removably secured to the first elongate mounting structure. A second plurality of LEDs may be removably secured to the second elongate mounting structure.

### CROSS REFERENCE TO RELATED APPLICATION

This application claims the benefit of U.S. Provisional Patent Application No. 60/744,030, filed Mar. 31, 2006, the disclosure of which is incorporated by reference herein in its entirety.

### BACKGROUND

The present disclosure relates generally to lighting or illumination assemblies and relates more particularly to lighting or illumination assemblies that include light emitting diodes (LEDs).

Illumination assemblies are used in a variety of diverse applications. Traditional illumination assemblies have used lighting sources such as incandescent or fluorescent lights, for example. More recently, other types of light emitting elements, and light emitting diodes (LEDs) in particular, have been used in illumination assemblies. LEDs have the advantages of small size, long life, and low power consumption. These advantages of LEDs make them useful in many diverse applications.

In some lighting applications, a number of LEDs may be used in combination, either to provide a relatively higher light intensity or to provide light over a relatively greater area. In some cases, a number of LEDs may be assembled in an array. LEDs in an array may be connected to each other and/or to other electrical systems by mounting the LEDs onto a printed circuit board substrate. LEDs may be mounted on a substrate by, for example, positioning the LEDs onto circuit board traces followed by bonding the components to the substrate using one of a number of known technologies, including wave soldering, reflow soldering, and attachment using conductive adhesives.

However, using these processes to bond LEDs to a substrate may, in some cases, involve package designs and processes that can be detrimental to LED performance and/or to assembly cost. In some cases, subjecting a packaged LED to soldering temperatures may have a negative impact on the packaging materials. While an adhesive assembly process may be employed, this may involve a time consuming thermal curing process that also subjects components to elevated processing temperatures and may provide electrical connections having relatively higher resistivity.

Therefore, a need remains for improved methods of mounting LEDs onto substrates. A need remains for improved mounting structures for securing LEDs, as well as LEDs that are adapted to be secured to such mounting structures.

### SUMMARY

The present disclosure pertains generally to LEDs and to structures for mounting LEDs.

Accordingly, in an illustrative but non-limiting example of the disclosure, an LED assembly is described. An LED assembly may include a substrate, an elongate mounting structure that is formed in or on the substrate, and an LED that includes a first mechanical attachment leg and a second mechanical attachment leg. The LED may be mechanically secured to the elongate mounting structure such that the elongate mounting structure extends between the first mechanical attachment leg and the second mechanical attachment leg.

In another illustrative but non-limiting example of the disclosure, a light producing apparatus is described. A light producing apparatus may include a substrate, an elongate mounting structure that may be formed in or on the substrate, and a plurality of LEDs. Each of the LEDs may include a first mechanical attachment leg and a second mechanical attachment leg and may be removably secured to the elongate mounting structure such that the elongate mounting structure extends between the first mechanical attachment leg and the second mechanical attachment leg.

In another illustrative but non-limiting example of the disclosure, a light producing array is described. A light producing array may include a substrate, a first elongate mounting structure that is formed in or on the substrate, and a second elongate mounting structure that is formed in or on the substrate. A first plurality of LEDs may be removably secured to the first elongate mounting structure. A second plurality of LEDs may be removably secured to the second elongate mounting structure.

These and other aspects of the present disclosure will be apparent from the detailed description below. In no event, however, should the above summaries be construed as limitations on the claimed subject matter, which subject matter is defined solely by the attached claims, as may be amended during prosecution.

### BRIEF DESCRIPTION OF THE FIGURES

The disclosure may be more completely understood in consideration of the following detailed description of the accompanying drawings, in which:

FIG. 1 is a schematic side view of an illustrative but non-limiting LED (light emitting diode) as described herein;

FIG. 2 is a schematic side view of an illustrative but non-limiting LED as described herein;

FIG. 3 is a schematic side view of an illustrative but non-limiting LED as described herein;

FIG. 4 is a schematic side view of an illustrative but non-limiting LED as described herein;

FIG. 5 is an exploded schematic side view of an illustrative but non-limiting LED assembly as described herein;

FIG. 6 is an exploded schematic side view of an illustrative but non-limiting LED assembly as described herein;

FIG. 7 is a schematic side view of an illustrative but non-limiting LED assembly as described herein;

FIG. 8 is a schematic top view of an illustrative but non-limiting light producing apparatus as described herein; and

FIG. 9 is a schematic top view of an illustrative but non-limiting light producing array as described herein.

### DETAILED DESCRIPTION

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

Weight percent, wt %, percent by weight, % by weight, and the like are synonyms that refer to the concentration of a substance as the weight of that substance divided by the weight of the composition and multiplied by 100.

The recitation of numerical ranges by endpoints includes all numbers subsumed within that range (e.g., 1 to 5 includes 1, 1.5, 2, 2.75, 3, 3.80, 4, and 5) and any range within that range.

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The present disclosure is applicable to illumination assemblies, and is more particularly applicable to illumination assemblies that provide illumination using LEDs. The illumination assemblies disclosed herein may be used for general lighting purposes, e.g., to illuminate an area, or for providing information to a viewer by selective illumination of different areas of the assembly as in an information display. Such assemblies are suitable for use in backlight displays, signs, and other lighting applications that require a significant amount of light.

As used herein, the terms “LED” and “light emitting diode” refer generally to light emitting semiconductor elements with contact areas for providing power to the diode. A III-V semiconductor light emitting diode may be formed, for example, from a combination of one or more Group III elements and one or more Group V elements. Suitable materials include nitrides, such as gallium nitride or indium gallium nitride, and phosphides, such as indium gallium phosphide. Other types of III-V materials can also be used, as can inorganic materials from other groups of the periodic table.

In some instances, LEDs can be top emitting or side-emitting, such as those described in West et al., U.S. Patent Publication No. 2004/0,233,665 A1.

LEDs can be selected to emit at any desired wavelength, such as in the red, green, blue, ultraviolet, or infrared spectral regions. In an array of LEDs, the LEDs can each emit in the same spectral region, or can emit in different spectral regions. Different LEDs may be used to produce different colors where the color of light emitted from the light emitting element is selectable. Individual control of the different LEDs leads to the ability to control the color of the emitted light. In addition, if white light is desired, then a number of LEDs emitting light of different colors may be provided, whose combined effect is to emit light perceived by a viewer to be white.

Another approach to producing white light is to use one or more LEDs that emit light at a relatively short wavelength and to convert the emitted light to white light using a phosphor wavelength converter. White light is light that stimulates the photoreceptors in the human eye to yield an appearance that an ordinary observer would consider “white.” Such white light may be biased to the red (commonly referred to as warm white light) or to the blue (commonly referred to as cool white light). Such light can have a color rendering index of up to 100.

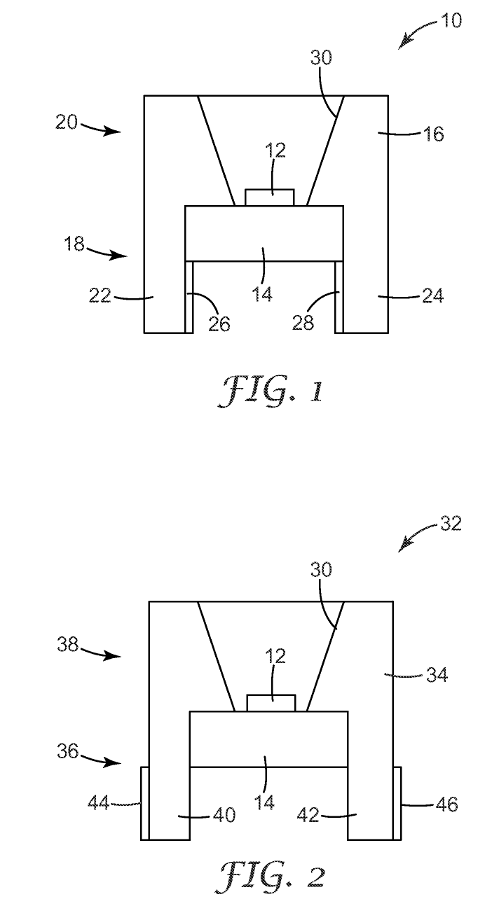

FIG. 1 provides an illustrative but non-limiting view of an LED 10. LED 10 includes an LED die 12 that is in thermal contact with a heat sink 14. Although LED 10 is shown as including only a single LED die 12, it should be noted that LED 10 may, if desired, include two or more LED dies 12 to achieve a desired color. For example, LED 10 may include one or more red-emitting LED die(s) and/or one or more green-emitting die(s) and/or one or more blue-emitting die(s).

LED die 12 may include any suitable LED die. For example, LED die 12 may, if desired, include distinct p- and n-doped semiconductor layers, substrate layers, buffer layers, and superstrate layers. The primary emitting surface, bottom surface, and side surfaces of LED die 12 may, as illustrated, form a simple rectangular arrangement, but other known configurations are also contemplated, e.g., angled side surfaces forming, for example, a truncated pyramid shape that can either be upright or inverted. Electrical contacts to LED die 12 are not shown for simplicity, but may be provided on any of the surfaces of LED die 12 as is known.

Heat sink 14 may be formed of any suitable material having a sufficiently high thermal conductivity, such as one or more of copper, nickel, gold, aluminum, tin, lead, silver, indium, zinc oxide, beryllium oxide, aluminum oxide, sapphire, diamond, aluminum nitride, silicon carbide, graphite, magnesium, tungsten, molybdenum, silicon, polymeric binders, inorganic binders, glass binders, and combinations thereof.

In some instances, heat sink 14 may act as a low thermal resistance pathway so that heat generated by LED die 12 may be directed away from LED die 12 and out of LED 10. Heat sink 14 may be in direct contact with LED die 12. In some instances, LED die 12 may be thermally connected to heat sink 14 through, for example, a thermally conductive adhesive.

LED 10 may include, as illustrated, an LED body 16. In some instances, heat sink 14 may be secured to LED body 16. Heat sink 14 may be permanently secured to LED body 16 using any appropriate technique such as adhering, bonding, welding and the like. In some cases, heat sink 14 may be integrally formed with LED body 16. If desired, heat sink 14 may be removably secured to LED body 16 using any suitable technique.

LED body 16 may be formed of any suitable material. Examples of appropriate materials for LED body 16 include polymeric materials suitable for injection molding, such as nylon, polyetherimide, polyamidimide, polyetheretherketone, polysulfone, cyclic olefin copolymer, polymethylmethacrylate, polycarbonate, or the like and may be neat resin or may contain fillers to provide strength or thermal conductivity, or other desirable properties. Other examples of appropriate materials for LED body 16 include metals, for example aluminum, steel, brass, bronze, or metal alloys, any of which could be suitable for machining, stamping, casting, turning, etc. Further examples of suitable materials are ceramics such as alumina, calcium titanate, barium titanate, zirconia, etc.

LED body 16 defines a lower portion 18 and an upper portion 20. In some instances, lower portion 18 may be adapted to secure LED 10 to a substrate (not shown in this Figure), as well as to provide thermal and electrical communication between LED die 12 and the substrate to which LED 10 may be secured.

Lower portion 18 may include a first leg 22 and a second leg 24. In some instances, as will be described hereinafter, first leg 22 may be referred to as a first mechanical attachment leg and second leg 24 may be referred to as a second mechanical attachment leg. A first electrode 26 is disposed along an interior surface of the first leg 22 and a second electrode 28 is disposed along an interior surface of the second leg 24. First electrode 26 and/or second electrode 28 may be electrically connected to LED die 12 in any suitable manner and may be used to provide electrical communication from a circuit board or other substrate to which LED 10 may be secured.

In some cases, LED 10 may include more than one LED die 12. In such cases, LED 10 may include more than two legs. For example, if LED 10 includes two LED dies 12, LED 10 may include a total of four legs, each leg bearing a single electrode that is in electrical communication with a respective LED die 12. Alternatively, if LED 10 includes, for example, two LED dies 12, LED 10 may have only two legs, such as first leg 22 and second leg 24. First leg 22 may include two distinct, electrically separate electrodes and second leg 24 may include two distinct, electrically separate electrodes so that the LED dies 12 may be individually powered and/or controlled.

In some cases, LED body 16 may be formed of an electrically conductive material. In such instances, it may be useful to dispose an electrically insulating material between each electrode and LED body 16. An electrically insulating material can be disposed between first electrode 26 and LED body 16, and/or between second electrode 28 and LED body 16.

As noted, LED body 16 also includes upper portion 20 that may, in some instances, be adapted to influence the light emanating from LED die 12. In some cases, upper portion 20 may include a reflective surface 30. In some cases, reflective surface 30 may be positioned to reflect at least a portion of light emitted by LED die 12. For example, reflective surface 30 may be configured to reflect edge-emitted light from LED die 12 such that the light is reflected in an intended direction. Reflective surface 30 may be formed of any suitable material or materials. In some instances, reflective surface 30 may be specularly reflective. In some cases, reflective surface 30 may be diffusively reflective. Reflective surface 30 may, if desired, include a multilayer polymeric reflective film such as Vikuiti™ ESR film, which is available from 3M Company, St. Paul, Minn. In some instances, reflective surface 30 may also include an encapsulant or additional optical elements such as lenses, if desired.

FIG. 2 provides an illustrative but non-limiting view of an LED 32 that includes LED die 12 thermally secured to heat sink 14. LED 32 includes as an LED body 34. LED die 12 and heat sink 14 are discussed above with respect to FIG. 1. LED body 34 includes a lower portion 36 and an upper portion 38. Upper portion 38 includes reflective surface 30 as discussed above with respect to FIG. 1.

Lower portion 36 may include a first leg 40 and a second leg 42. In some instances, as will be described hereinafter, first leg 40 may be referred to as a first mechanical attachment leg and second leg 42 may be referred to as a second mechanical attachment leg. A first electrode 44 is disposed along an exterior surface of the first leg 40 and a second electrode 46 is disposed along an exterior surface of the second leg 42. First electrode 44 and/or second electrode 46 may be electrically connected to LED die 12 in any suitable manner and may be used to provide electrical communication from a circuit board or other substrate to which LED 32 may be secured.

In some instances, LED 32 may include more than one LED die 12, and therefore may, if desired, include a total of four electrodes. As discussed with respect to FIG. 1, additional electrodes may be accommodated either by including additional legs, or by placing more than one electrode on a single leg.

In some instances, lower portion 36 of LED body 34 may be formed of an electrically conductive material. In such instances, it may be useful to dispose an electrically insulating material between each electrode and LED body 34. An electrically insulating material can be disposed between first electrode 44 and first leg 40, and/or between second electrode 46 and second leg 42.

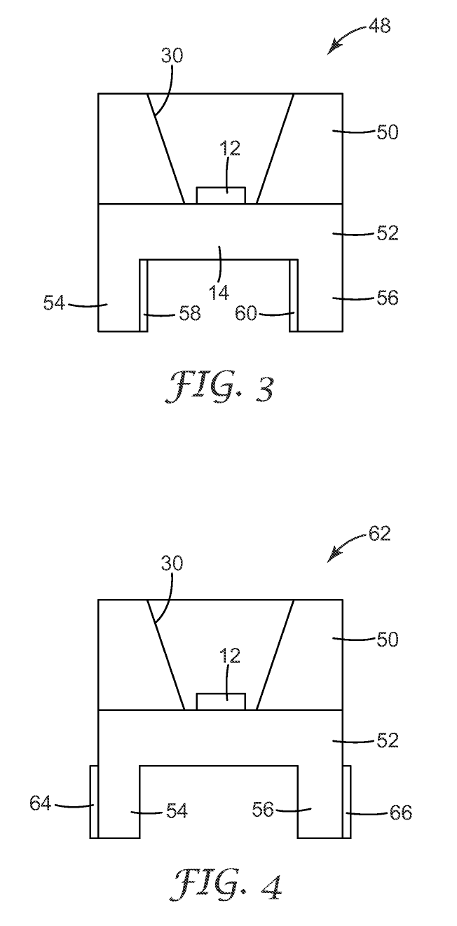

FIG. 3 provides an illustrative but non-limiting view of an LED 48. LED 48 includes an LED body 50 that is secured to a structured heat sink 52. LED die 12 is thermally secured to the structured heat sink 52. LED die 12 is as discussed above with respect to FIG. 1. LED body 50 may be formed of any suitable material, as discussed above with respect to FIG. 1. Similarly, structured heat sink 52 may be formed of any suitable material as discussed above with respect to FIG. 1.

Structured heat sink 52 includes a first leg 54 and a second leg 56. In some cases, first leg 54 may be referred to as a first mechanical attachment leg and second leg 56 may be referred to as a second mechanical attachment leg. A first electrode 58 is disposed along an interior surface of the first leg 54 and a second electrode 60 is disposed along an interior surface of the second leg 56. First electrode 58 and/or second electrode 60 may be electrically connected to LED die 12 in any suitable manner and may be used to provide electrical communication from a circuit board or other substrate to which LED 48 may be secured.

In some cases, structured heat sink 52 may be formed of an electrically conductive material. In such instances, it may be useful to dispose an electrically insulating material between each electrode and structured heat sink 52. An electrically insulating material can be disposed between first electrode 58 and structured heat sink 52, and/or between second electrode 60 and structured heat sink 52.

FIG. 4 provides an illustrative but non-limiting view of an LED 62. LED 62 includes an LED body 50 that is secured to a structured heat sink 52. LED die 12 is thermally secured to the structured heat sink 52. LED die 12 is as discussed above with respect to FIG. 1. LED body 50 may be formed of any suitable material, as discussed above with respect to FIG. 1. Similarly, structured heat sink 52 may be formed of any suitable material as discussed above with respect to FIG. 1.

Structured heat sink 52 includes a first leg 54 and a second leg 56. In some cases, first leg 54 may be referred to as a first mechanical attachment leg and second leg 56 may be referred to as a second mechanical attachment leg. A first electrode 64 is disposed along an exterior surface of the first leg 54 and a second electrode 66 is disposed along an exterior surface of the second leg 56. First electrode 64 and/or second electrode 66 may be electrically connected to LED die 12 in any suitable manner and may be used to provide electrical communication from a circuit board or other substrate to which LED 48 may be secured.

In some cases, structured heat sink 52 may be formed of an electrically conductive material. In such instances, it may be useful to dispose an electrically insulating material between each electrode and structured heat sink 52. An electrically insulating material can be disposed between first electrode 64 and structured heat sink 52, and/or between second electrode 66 and structured heat sink 52.

FIG. 5 provides an illustrative but non-limiting example of an LED assembly 68. In particular, FIG. 5 is an exploded view of LED 10 (FIG. 1) positioned over a substrate 70 that includes a surface 72. While LED 10 is used for illustration, it should be noted that LED 48, as shown in FIG. 3, could also be used within LED assembly 68.

A mounting structure 74 is disposed on surface 72. Mounting structure 74 may be separately formed and then subsequently secured to surface 72 of substrate 70. In some instances, mounting structure 74 may be integrally formed with substrate 70. If mounting structure 74 is integrally formed with substrate 70, this can mean that mounting structure 74 and substrate 70 are formed at the same time, as a single or unitary piece. Molding and extrusion are examples of processes that may, if desired, be used to integrally form mounting structure 74 with substrate 70.

It can be seen that mounting structure 74 has a width that is complementary to the space between first leg 22 and second leg 24 of LED 10 such that mounting structure 74 extends between first leg 22 and second leg 24. In some instances, mounting structure 74 may have a height that corresponds to a length of first leg 22 and/or second leg 24. It will be recognized that mounting structure 74 may be elongate, and thus may have a length that may be defined as extending in a plane that is orthogonal to the plane defining the width.

In some instances, mounting structure 74 may be a longitudinally-extending rib that has a substantially uniform cross-sectional profile. In some cases, mounting structure 74 may have a square or rectangular cross-sectional profile. While not illustrated, mounting structure 74 may have a substantially square or rectangular profile, but may include one or more indentations or protrusions that may be configured to interact with corresponding shapes or structures formed within or on first leg 22 and/or second leg 24 of LED 10, thereby more strongly holding LED 10 onto mounting structure 74.

LED 10 may be mechanically secured to mounting structure 74. In some cases, LED 10 may be press-fitted onto mounting structure 74. LED 10 may, if desired, be snap-fitted onto mounting structure 74. In some instances, LED 10 may have an interference fit with mounting structure 74 that is sufficient to secure LED 10. In some cases, LED 10 may be removably secured to mounting structure 74. In some cases, a single LED 10 may be secured to mounting structure 74. If desired, two, three or a greater number of LEDs 10 may be secured to a single mounting structure 74.

Mounting structure 74 can be seen as including a first side 76 that may interact with first electrode 26 positioned on an interior surface of first leg 22 as well as a second side 78 that may interact with second electrode 28 positioned on an interior surface of second leg 24. First side 76 includes an electrical contact 77 that is positioned and configured to provide electrical contact with first electrode 26. Similarly, second side 78 includes an electrical contact 79 that is positioned and configured to provide electrical contact with second electrode 28. If mounting structure 74 is formed of an electrically conductive material, insulating materials may be used to isolate electrical contacts 77 and 79 from mounting structure 74.

If more than one LED 10 is secured to mounting structure 74, first side 76 may include an elongate electrical contact 77 that is positioned and configured to provide electrical contact with each first electrode 26 (of each LED 10) and second side 78 may include an elongate electrical contact 79 that is positioned and configured to provide electrical contact with each second electrode 28 (of each LED 10). In some instances, electrical contact 77 and/or electrical contact 79 may form several distinct electrical contacts so that one or more of a number of LEDs 10 may be individually powered and/or controlled. In some embodiments, the mounting structure 74 has two or more pairs of electrical contacts 77, 79 to individually power and/or control two or more LED dies 12. For example, the mounting structure 74 can have a red LED pair of electrical contacts 77, 79, a blue LED pair of electrical contacts 77, 79, and a green LED pair of electrical contacts 77, 79.

In other embodiments, an LED can have multiple LED dies and each LED die has a single lead per LED die and one common ground. Thus, a LED having a red, blue and green LED die can be configured with four leads as opposed to six leads as described above. Thus, multiple circuit configurations are contemplated and are within the scope of this disclosure.

First leg 22, which as noted above may be referred to as a first mechanical attachment leg, may fit alongside first side 76 of mounting structure 74. Similarly, second leg 24, which as noted above may be referred to as a second mechanical attachment leg, may fit alongside second side 78 of mounting structure 74. Thus, the first and second mechanical attachment legs may cooperate with mounting structure 74 to provide a mechanical, possibly removable, attachment between LED 10 and substrate 70.

Moreover, surface 72 of substrate 70 may include a circuit trace or a patterned conductive layer (not illustrated) that connects to the electrical contacts 77, 79 on or in the mounting structure 74 that provides electrical communication between LED 10 and one or more control circuits. If present, a circuit trace or patterned conductive layer may be formed in any suitable manner and from any suitably electrically conductive materials such as copper, nickel, gold, aluminum, tin, lead, silver, indium, gallium, and combinations thereof. A circuit trace or patterned conductive layer may be separately formed and subsequently secured to surface 72.

In some cases, a circuit trace or patterned conductive layer may be formed directly on surface 72. For example, a patterned conductive layer may be formed and patterned using any suitable technique known in the art, such as chemical etching, photolithography, chemical-vapor deposition, ink-jet printing, screen printing, sputtering, electroplating, etc.

In some cases, at least a portion of surface 72 may include a reflective layer or coating to reflect any light incident thereon. Any highly reflective material may be used for such a layer or coating. In some instances, it is considered that a reflective layer or coating may cover at least portions of surface 72 that are not covered by any patterned conductive layer that may be present on surface 72.

Substrate 70 may be flexible or non-flexible, and may be formed of any suitable material. In some cases, substrate 70 may be molded, extruded or otherwise formed to include mounting structure 74 as a unitary or integral part of substrate 70. Examples of suitable materials for forming a non-flexible substrate 70 include copper and copper alloys, aluminum and aluminum alloys, steel, tin, FR4, thermally conductive polymers, etc. Examples of suitable materials for forming a flexible substrate 70 include polyimides, polyesters, and Vikuiti™ ESR film, which is a multilayer polymeric reflective film available from 3M Company, St. Paul, Minn.

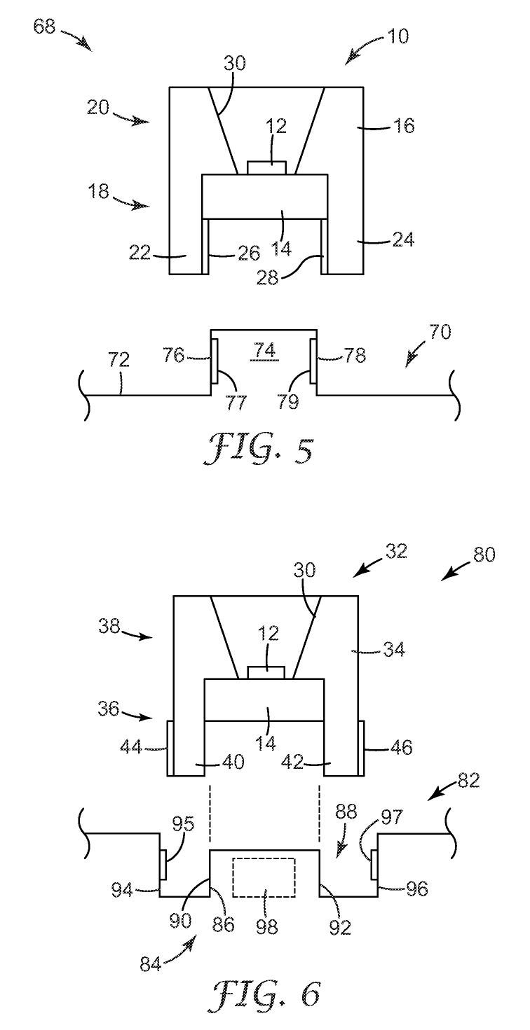

FIG. 6 provides an illustrative but non-limiting example of an LED assembly 80. In particular, FIG. 6 is an exploded view of LED 32 (FIG. 2) positioned over a substrate 82. While LED 10 is used for illustration, it should be noted that LED 62, as shown in FIG. 4, could also be used in LED assembly 68.

Substrate 82 includes a mounting structure 84. Mounting structure 84 includes a mounting rib 86 that is disposed within a channel 88. Substrate 82 may, if desired, include a conductive pattern (not shown) and/or a reflective layer or coating (not shown), and two or more pairs of electrical contacts 95, 97 to individually power and/or control two or more LED dies 12, as discussed above with respect to substrate 70 of FIG. 5.

In some embodiments, the mounting structure 84 is a channel 88 having a planar bottom surface (not shown) formed in the substrate 82. In theses embodiments, the LED 32, 62 can have a planar bottom surface (not shown) that mates with the planar bottom surface of the channel 88 of substrate 82, thus the mounting rib 86 may not be present in these embodiments.

Mounting rib 86 can be seen as including a first side 90 that may contact an inner surface of first leg 40 and a second side 92 that may contact an inner surface of second leg 42. Channel 88 may include a first channel wall 94 that may interact with first electrode 44 positioned on an exterior surface of first leg 40 and a second channel wall 96 that may interact with second electrode 46 positioned on an exterior surface of second leg 42. First channel wall 94 may include an electrical contact 95 that is positioned and configured to provide electrical contact with first electrode 44. Similarly, second channel wall 96 may include an electrical contact 97 that is positioned and configured to provide electrical contact with second electrode 46.

Electrical contacts 95 and 97 could be moved to first and second sides 90 and 92, respectively, of mounting rib 86 if, for example, LED 10 (FIG. 1) or LED 48 (FIG. 3) is used. If channel 88 and/or mounting rib 86 is formed of an electrically conductive material, insulating materials may be used to isolate electrical contacts 95 and 97.

In some instances, if desired, mounting rib 86 may be hollow, and may include an aperture 98 (shown in phantom). In some cases, a working fluid may be disposed within aperture 98 to aid in heat dispersion. The working fluid may be static, or may be pumped or otherwise circulated through aperture 98. Any suitable working fluid may be used, such as a fluid having a high heat transfer coefficient.

Mounting rib 86 and/or channel 88 may be sized to accommodate whichever LED is secured thereto. Channel 88 and/or mounting rib 86 may be formed in any suitable manner. In some cases, channel 88 and mounting rib 86 may be molded into substrate 82. If desired, channel 88 and mounting rib 86 may be formed by grinding or otherwise removing material from substrate 82. Substrate 82 may be formed of any suitable materials, such as those discussed with respect to substrate 70 (FIG. 5).

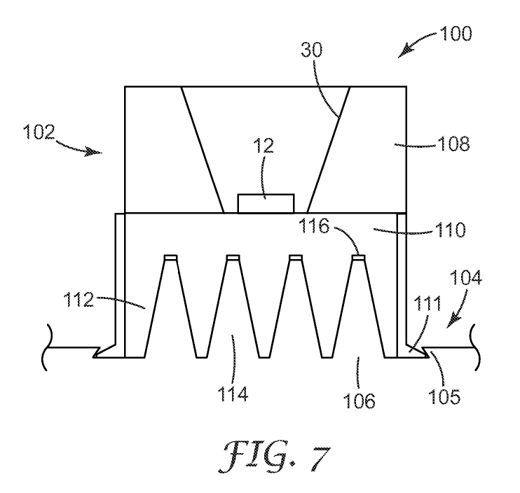

FIG. 7 provides an illustrative but non-limiting example of an LED assembly 100 that includes an LED 102 disposed on a substrate 104 bearing a structured mounting structure 106. LED 102 includes an LED die 12 disposed within an LED body 108. LED body 108 includes reflective surface 30, as discussed previously. LED 102 also includes a structured heat sink 110. Structured heat sink 110 may be formed of any suitable material, as discussed previously (e.g. those materials described for heat sink 14 of FIG. 1).

It can be seen that a lower side of structured heat sink 110 includes several or even a number of structures 112 that are complementary to several or even a number of corresponding structures 114 that are formed within structured mounting structure 106. This may, in some instances, provide greater contact surface area and thus may provide increased friction for mounting LED 102 to substrate 104. This may also provide improved heat transfer. In some instances, as illustrated, structured structures 114 may include circuit traces 116 that may be used to provide electrical communication with LED die 12. If desired, structured heat sink 110 may include a latch 111 or other protrusion that may interact with a notch 105 formed within substrate 104 to help secure LED 102 to substrate 104.

Any suitable technique may be used to form structure 112 and structure 114. In some instances, structure 112 and/or structure 114 may be formed via a microreplication process, via molding, extrusion, and the like. In some cases, structure 112 and/or structure 114 may be separately formed and then subsequently secured to structured heat sink 110 and/or substrate 106, respectively.

FIG. 8 provides an illustrative but non-limiting example of a light producing apparatus 118 that includes a substrate 120 and a mounting structure 122. In some instances, mounting structure 122 may be considered as being an elongate mounting structure. While mounting structure 122 is illustrated as a mounting rib extending from substrate 120, it should be noted that mounting structure 122 could also include a channel, as shown in FIG. 6, or even a structured mounting structure as shown in FIG. 7.

In the illustrated view, a total of four LEDs 124 are visible. It will be appreciated that in some instances, light producing apparatus 118 may include one, two or three LEDs 124. In some cases, light producing apparatus 118 may include a larger number of LEDs 124. In some instances, LEDs 124 may be uniformly or non-uniformly spaced, depending on the application. Mounting structure 122 is adapted to permit customized spacing.

Each LED 124 is mechanically secured to mounting structure 122. In some instances, each LED 124 may be may be press-fitted onto mounting structure 122. Each LED 124 may, if desired, be snap-fitted onto mounting structure 122. In some instances, each LED 124 may have an interference fit with mounting structure 122 that is sufficient to secure each LED 124. In some cases, each LED 124 may be removably secured to mounting structure 122.

In some embodiments, the interference fit allows an electrical connection by insulation displacement contact with an underlying conductor. In these embodiments, an insulative material or dielectric material covers at least a portion of the electrical contacts or electrodes on the LEDs and electrical contact is achieved by displacing at least a portion of the dielectric material as the LED is mechanically secured or pressed onto the mounting structure.

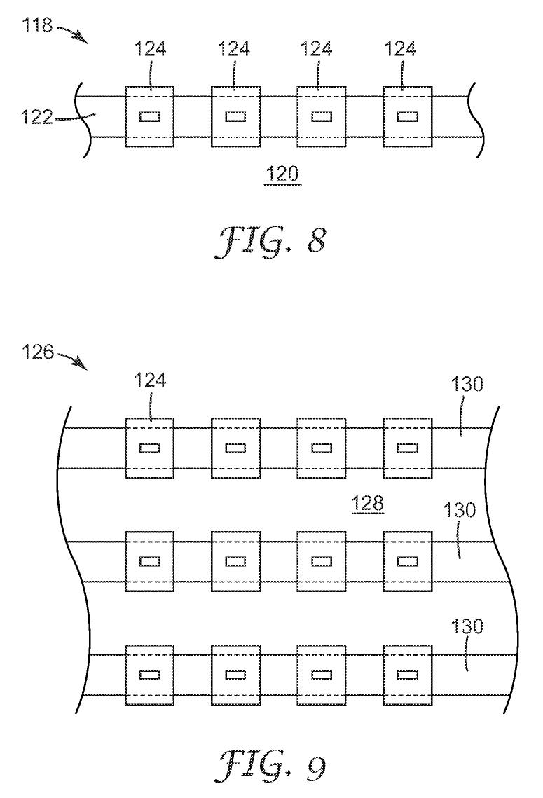

FIG. 9 provides an illustrative but non-limiting example of a light producing array 126 that includes a substrate 128 and several mounting structures 130. While a total of three mounting structures 130 are shown, it will be appreciated that light producing array 126 may include only two mounting structures 130, or may include many more than three mounting structures 130. Each mounting structure 130 may be considered to be an elongate mounting structure. While each mounting structure 130 is shown as being a mounting rib, it should be noted that each mounting structure could also include a channel or a structured mounting structure as discussed above.

In the illustrated view, a total of four LEDs 124 are seen secured to each mounting structure 130. It will be appreciated that in some instances, each mounting structure 130 may include one, two or three LEDs 124, or a larger number of LEDs 124.

Each LED 124 is mechanically secured to a mounting structure 130. In some instances, each LED 124 may be may be press-fitted onto a mounting structure 130. Each LED 124 may, if desired, be snap-fitted onto mounting structure 130. In some instances, each LED 124 may have an interference fit with a mounting structure 130 that is sufficient to secure each LED 124. In some cases, each LED 124 may be removably secured to a mounting structure 130.

The LED mounting structures described herein can be formed into any shape or cut down to any shape or size and then populated with the LEDs described herein to form the light producing apparatus and/or light producing array described herein.

The LED mounting structures described herein, such as light producing apparatus 118 (FIG. 8) and light producing array 126 (FIG. 9), may be used in a variety of different applications. For example, these light producing structures may be employed in displays, backlit signs, and in decorative and general lighting.

All references and publications cited herein are expressly incorporated herein by reference in their entirety into this disclosure. Illustrative embodiments of this disclosure are discussed and reference has been made to possible variations within the scope of this disclosure. These and other variations and modifications in the disclosure will be apparent to those skilled in the art without departing from the scope of the disclosure, and it should be understood that this disclosure is not limited to the illustrative embodiments set forth herein. Accordingly, the disclosure is to be limited only by the claims provided below.

We claim:

1. An LED assembly, comprising:
a substrate;
an elongate mounting structure formed on the substrate; and
an LED comprising a first mechanical attachment leg and a second mechanical attachment leg, the LED mechanically secured to the elongate mounting structure such that the elongate mounting structure extends between the first and second mechanical attachment legs.

2. The LED assembly of claim 1, wherein the first mechanical attachment leg is parallel to the second mechanical attachment leg.

3. The LED assembly of claim 1, wherein the first mechanical attachment leg and the second mechanical attachment leg secure the LED to the elongate mounting structure.

4. The LED assembly of claim 1, wherein the LED further comprises:
a heat sink;
an LED die in thermal contact with the heat sink; and
a reflective surface disposed to reflect a portion of light emitted by the LED die.

5. The LED assembly of claim 4, wherein the LED further comprises an LED body, the LED body encompassing the reflective surface.

6. The LED assembly of claim 5, wherein the LED body is adapted to be mechanically secured to the elongate mounting structure.

7. The LED assembly of claim 6, wherein the LED body forms the first mechanical attachment leg and the second mechanical attachment leg.

8. The LED assembly of claim 4, wherein the heat sink is adapted to be mechanically secured to the elongate mounting structure.

9. The LED assembly of claim 8, wherein the heat sink forms the first mechanical attachment leg and the second mechanical attachment leg.

10. The LED assembly of claim 1, wherein the substrate comprises a circuit board.

11. The LED assembly of claim 10, wherein the LED comprises conductive leads extending to the circuit board.

12. The LED assembly of claim 10, wherein the circuit board comprises a conductive pattern formed on the substrate.

13. The LED assembly of claim 1, wherein the substrate comprises a material having a high thermal conductivity.

14. The LED assembly of claim 1, wherein the elongate mounting structure is solid.

15. The LED assembly of claim 1, wherein the elongate mounting structure is hollow.

16. The LED assembly of claim 15, further comprising a fluid disposed within the elongate mounting structure.

17. The LED assembly of claim 1, wherein the elongate mounting structure comprises a rib extending beyond a surface of the substrate.

18. The LED assembly of claim 17, wherein the rib comprises a structured rib.

19. The LED assembly of claim 18, wherein the LED comprises a surface complementary to the structured rib.

20. The LED assembly of claim 1, wherein the elongate mounting structure comprises a rib that is disposed within a channel formed within the substrate.

21. The LED assembly of claim 1, wherein the LED is removably attached to the substrate.

22. The LED assembly of claim 1, wherein the substrate comprises a structured substrate.

23. The LED assembly of claim 1, wherein the LED further comprises a first electrode disposed on an interior surface of the first mechanical attachment leg and a second electrode disposed on an interior surface of the second mechanical attachment leg.

24. The LED assembly of claim 23, wherein the first mechanical attachment leg and the second mechanical attachment leg extend further than any other portion of the LED.

25. The LED assembly of claim 1, wherein the LED further comprises a first electrode disposed on an exterior surface of the first mechanical attachment leg and a second electrode disposed on an exterior surface of the second mechanical attachment leg.

26. The LED assembly of claim 25, wherein the first mechanical attachment leg and the second mechanical attachment leg extend further than any other portion of the LED.

27. The LED assembly of claim 1, wherein the LED is snap-fitted onto the elongate mounting structure.

28. The LED assembly of claim 1, wherein the LED has an interference fit with the elongate mounting structure.

29. The LED assembly of claim 1, wherein the LED has an interference fit with the elongate mounting structure and comprises an insulation displacement connection to an underlying conductor.

30. The LED assembly of claim 1, wherein the elongate mounting structure has a uniform rectangular cross-section.

31. A light producing apparatus, comprising:
a substrate;
an elongate mounting structure formed on the substrate; and
a plurality of LEDs removably secured to the elongate mounting structure, each of the plurality of LEDs comprising a first mechanical attachment leg and a second mechanical attachment leg, each of the first mechanical attachment leg and the second mechanical attachment leg being adapted to secure said LED to the substrate such that the elongate mounting structure extends between the first and second mechanical attachment legs.

32. The light producing apparatus of claim 31, further comprising a conductive pattern formed on the substrate.

33. The light producing apparatus of claim 31, wherein the substrate comprises a material having a high thermal conductivity.

34. The light producing apparatus of claim 31, wherein the elongate mounting structure is solid.

35. The light producing apparatus of claim 31, wherein the elongate mounting structure is hollow.

36. The light producing apparatus of claim 35, further comprising a fluid disposed within the elongate mounting structure.

37. The light producing apparatus of claim 31, wherein the elongate mounting structure comprises a rib extending beyond a surface of the substrate.

38. The light producing apparatus of claim 31, wherein the elongate mounting structure comprises a rib disposed within a channel formed within the substrate.

39. The light producing apparatus of claim 31, wherein the substrate comprises a structured substrate.

40. The light producing apparatus of claim 31, wherein at least some of the plurality of LEDs further comprise a first electrode disposed on an interior surface of the first mechanical attachment leg and a second electrode disposed on an interior surface of the second mechanical attachment leg.

41. The light producing apparatus of claim 31, wherein at least some of the plurality of LEDs further comprise a first electrode disposed on an exterior surface of the first mechanical attachment leg and a second electrode disposed on an exterior surface of the second mechanical attachment leg.

42. A light producing array, comprising:
a substrate;
a first elongate mounting structure formed on the substrate;
a second elongate mounting structure formed on the substrate;
a first plurality of LEDs removably secured to the first elongate mounting structure; and
a second plurality of LEDs removably secured to the second elongate mounting structure.

43. The light producing array of claim 42, wherein at least one of the first elongate mounting structure and the second elongate mounting structure comprise a rib extending beyond a surface of the substrate.

44. The light producing array of claim 42, wherein the rib comprises a uniform rectangular cross-section.

45. The light producing array of claim 42, wherein at least one of the first elongate mounting structure and the second elongate mounting structure comprise a rib disposed within a channel formed within the substrate.

46. The light producing array of claim 42, wherein at least some of the first plurality of LEDs and at least some of the second plurality of LEDs comprise a first mechanical attachment leg and a second mechanical attachment leg, each of the first mechanical attachment leg and the second mechanical attachment leg being adapted to secure the LED to the first elongate mounting structure or the second elongate mounting structure.

47. The light producing array of claim 46, at least some of the first plurality of LEDs and at least some of the second plurality of LEDs further comprising a first electrode disposed on an interior surface of the first mechanical attachment leg and a second electrode disposed on an interior surface of the second mechanical attachment leg.

48. The light producing array of claim 46, at least some of the first plurality of LEDs and at least some of the second plurality of LEDs further comprising a first electrode disposed on an exterior surface of the first mechanical attachment leg and a second electrode disposed on an exterior surface of the second mechanical attachment leg.

49. The light producing array of claim 42, further comprising a third elongate mounting structure formed on the substrate and a third plurality of LEDs removably secured to the third elongate mounting structure.

50. The light producing array of claim 49, further comprising a plurality of elongate mounting structure formed on the substrate and a plurality of LEDs removably secured to the fourth elongate mounting structure.
